(19) United States
(12) Patent Application Publication
(10) Pub. No.: US 2009/0091342 A1
(43) Pub. Date: Apr. 9, 2009

(54) Node Extender for In-Circuit Test Systems

(75) Inventors: Dennis L. Dyer, Loveland, CO (US); Dayton Norrgard, Fort Collins, CO (US); Eddie L. Williamson, Fort Collins, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 11/866,413

(22) Filed: Oct. 3, 2007

(51) Int. Cl. G01R 1/04; G01R 31/28

(52) U.S. Cl. 324/754

(57) ABSTRACT

A node extender adaptor to enable existing in-circuit test systems to qualify printed circuit boards with a node count larger than the number of channels available on the in-circuit tester. The node extender adaptor routes signal channels within the in-circuit test platform to a probe from multiple probes in a test fixture. The probes connect to nets on a PCB undergoing qualification tests. The node extender adaptor sits atop test resources. A custom made test fixture attached onto the node extender adaptor. The node extender adaptor comprises multiple channel router line cards. Switches on the channel router line cards facilitate the switching of channels to one of the multiple probes.

### BACKGROUND OF THE INVENTION

In-Circuit Test (ICT) describes using mechanical probes, electronic circuitry and test software to qualify a printed circuit board (PCB). Examples of ICT systems are the Medalist 3070 from Agilent Technologies, Inc. of Santa Clara, Calif. and the TS 121 from Teradyne.

FIG. 1 is a block diagram of an ICT system (“tester”). The tester 102 comprises a test platform 104, a test resource interface 106, a test fixture 108 and a PCB 110. The test platform 104 can be readied to qualify the PCB 110 for production through custom software and hardware options of the test platform 104. The hardware options available to customize the tester 102 are, for example, test resources. The test resources can be line cards comprising electrical circuitry and are located within the test platform 104.

The test resources connect to components of the tester 102 via a test resource interface 106. The test resource interface 106 is a bed-of-nails test-heads comprising individual pins heads (‘test resource pins’). The test fixture 108 (‘fixture’), having many mechanical probes, is mounted over the test resource interface 106. The PCB 110 under test is mounted on the fixture 108 such that the fixture probes make electrical contact with various nodes on the PCB under test.

The test resources within the test platform 104 comprise electrical circuitry to provide stimuli, receive signals, and measure components on the PCB 110. The test resource interface 106 is an interface for the test platform 104 to the fixture 108 and the PCB 110.

A channel can represent a specific test resource of the test platform 104 or a path from the test resource to a net on the PCB 110. Hardware, software and functional tests are examples of test sequences initiated by the test platform 104 to identify defects in the PCB 110.

The test resource interface 106 can also provide access to the PCB 110 for secondary electronic circuitry (not shown) that is housed outside the confines of the ICT system 102.

The fixture 108 can have active or passive electronics incorporated within its structure. The fixture provides an electrical connection to a specific point, or a netlist (‘net’), on the PCB. A node can identify a connection of two or more devices to an electrical net on the PCB. However, not all nodes are accessible via a probe or a pin. A node count defines the number of accessible nodes on a PCB.

Each fixture 108 is custom designed for a particular PCB layout. Test sequences are written to qualify the PCB 110 using limitations imposed by the design of the custom fixture 108.

As node counts increase due to electrical designs incorporating smaller components or as a result of densely laid out PCBs, access to all available nets on the PCB 110 can be limited by the number of channels of the test platform 104.

Presently, qualifying a complex PCB with a node count greater than the number of channels in a tester 102 can entail segmenting the PCB 110, grouping the PCB 110 into clusters or performing a limited access test sweep. It can also require the design of at least two fixtures.

Unfortunately, fixtures and test sequences are expensive to design and can cost in excess of $10,000.

Purchasing a new test platform with sufficient channels to test a high node count PCBs is a solution available to manufacturers. This is another monetary set back for manufacturing companies as test platforms cost approximately $500,000.

Accordingly, a need exists to test high node count PCBs on existing ICT systems without having to invest in additional fixtures and test sequences or without having to replace the test platform 104 altogether.

### BRIEF DESCRIPTION OF THE DRAWINGS

FIG. 1 is a block diagram of an in-circuit test system known in the art;

FIG. 2 is a block diagram illustrating a node extender adaptor in an in-circuit test system;

FIG. 3 is a schematic circuit diagram illustrating the test resource pins, the adaptor and the fixture;

FIG. 4 is a vertical cross sectional view of the PCB, the fixture, the adaptor and the test resources;

FIG. 5 is a flow chart illustrating the method of operating the adaptor;

FIGS. 6A-C illustrates plan views of the test resources and the adaptor; and

FIGS. 7A-B are simplified illustrations of a channel router line card.

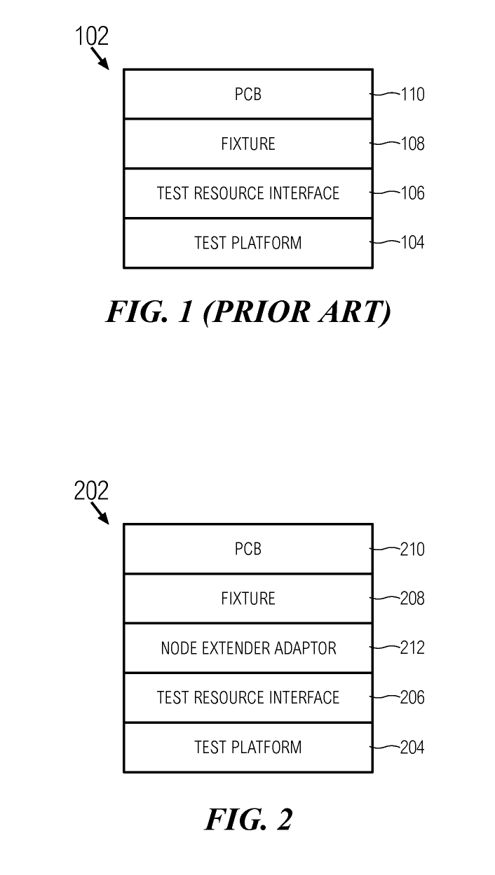

### DETAILED DESCRIPTION

The invention extends the use of current and future ICT systems to complex PCBs with a node count greater than the maximum number of channels available on the tester (‘high node count’). In older testers with a capacity of 2000 channels, or the Medalist 3070 system from Agilent Technologies with a channel capacity of 5184 channels, a high node count PCB can be identified as a PCB with a node count in excess of 2000 nets or 5184 nets respectively.

The invention reduces the number of custom fixtures required for a PCB line undergoing qualification. This allows for a reduction in the design and development time of custom fixtures for an ICT system. A concomitant benefit is a reduction in the overall test and qualification times for a complex PCB—as the qualification tests can be done with fewer fixtures. Embodiments of invention can be modular in design and the embodiments can be reused for different PCB qualification lines. The invention results in a large dollar savings for manufacturers by providing them with a scalable, modular and backward compatible option to expand the scope of existing testers.

The invention is a node extender adaptor (‘adaptor’) that is secured between the test platform and the fixture of an existing tester. The adaptor connects single channels to multiple nets on the PCB. It employs switches to electrically connect single pins of the test resource interface to multiple probes in the fixture. An overall qualification testing code can incorporate test sequences and instructions to switch individual channels to a designated probe.

The switches employed by the adaptor can be exemplified as electrical relays, electromechanical relays, field effect transistor switches or digital switches.

FIG. 2 is a block diagram of a tester 202 incorporating the inventive adaptor 212. A test platform 204 comprising test resources has a test resource interface 206 to output and receive electrical signals. The adaptor 212 attaches to the test resource interface 206 and electrically connects to the channels of the test resources within the test platform 204.

A custom fixture 208 attaches onto the adaptor 212. A PCB 210 undergoing test is clamped atop the fixture 208. When the qualification tests begin, a vacuum force or a mechanical force is applied by the fixture 208 to engage the PCB 210 down onto the probes on the fixture 208.

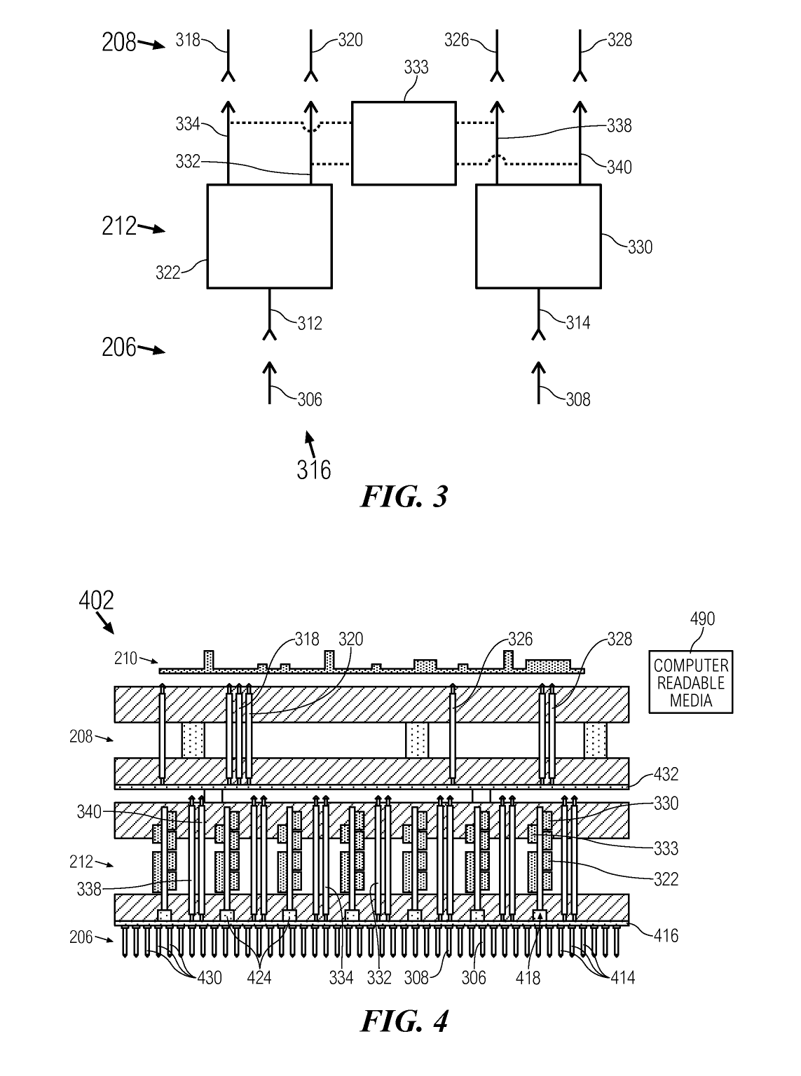

FIG. 3 is a schematic representing a design of the inventive adaptor 212. FIG. 3 identifies the test resource interface 206, the adaptor 212 and the fixture 208.

FIG. 3 also identifies test resource pins 306 and 308, switches 322, 330 and 333, probes 318, 320, 326 and 328 as well as interconnects 332, 334, 338 and 340.

The aspect of the invention described in FIG. 3 ‘multiplies’ the number of channels available in an ICT by a factor of two. This is achieved by routing a test resource pin to one of two probes on the fixture 208 with the aid of a switch.

In FIG. 3, the test resource interface 206 comprises two test resource pins 306 and 308. Two signal channels from within the test platform 204 of FIG. 2 (not shown in FIG. 3) are connected to the two pins 306 and 308. The two test resource pins 306 and 308 connect to two mating interconnects 312 and 314 on the adaptor 212.

A path 316 identifies the test resource pin 306 and two probes 318 and 320 on the fixture 208. The test resource pin 306 can be connected to one of two nets on the PCB 210 via the probes 318 and 320 with the switch 322. To illustrate, the switch 322 connects the test resource pin 306 to either the probe 318 or the probe 320 via the interconnects 334 or 332 when the switch 322 receives instruction. The control signal for energizing the switch 322 can be routed through the adaptor 212 or the test resource interface 206.

Similarly, the test resource pin 308 can connect to one of two nets on the PCB 210 via the interconnects 338 or 340 and onto probes 326 or 328 when the switch 330 receives instruction.

The adaptor 212 shown in FIG. 3 describes a third switch 333, also termed a diagnostic test switch 333, that enables short-circuit testing within the tester 202 and forms a level of redundancy in the overall tester design. The switch 333 can electrically connect the interconnects 332 and 334 from the output of the switch 322 to the interconnects 340 and 338 associated with the switch 330. The inclusion of the switch 333 also provides system level diagnostics for the switches 322 and 330.

The switches described in the adaptor 212 of FIG. 3 can be electrical relays readily available in the industry. Examples of electrical relay designs that can be employed are double-pole-single-throw, double-pole-double-throw and single-pole-single-throw (SPST) relays. If an SPST is conceptualized for the switches 322, 330 and 333, two units of SPST relays for each switch unit are necessary for routing the test resource pins 306 and 308 to their respective outputs.

FIG. 4 is a section view of the tester 202 embodying the inventive concept. The test resource interface 206, the adaptor 212, the fixture 208 and the PCB 210 of the tester 202 are identified in FIG. 4.

The test resource interface 206 comprising the test resource pins 306, 308 and 414 connect signal channels from within the test platform 204 (not shown in FIG. 4) to an adaptor motherboard 416. The adaptor motherboard 416 is a part of the overall adaptor 212 design.

The adaptor motherboard 416 is an interface plane designed to route the test interface pins 306, 308, 414 and 430 through to channel router line cards 424 or 418. The channel router line cards 424 or 418 can be removed or reused for other PCB line qualification tests as the design of the adaptor 212 can be modular and scalable.

The tester of FIG. 4 uses the schematic design of FIG. 3 to exemplify the aspects of the invention. The test resource pin 306 connects to the input of the switch 322 on the channel router line card 418. The switch 322 connects the test resource pin 306 to one of two interconnects 332 or 334 when the switch 322 is energized. These interconnects can be, for example, mechanical pins, a printed circuit board, a connector cable or flexible wire cable. The interconnects are also routed from the output of the switches 322, 330 and 333 of the channel router line card 418 through the adaptor motherboard 416.

The switch 322 and other switches within the node extender adaptor 212 are manipulated by control signals sent through the adaptor motherboard 416. In the tester 402, test resource interface pins 430 are part of a serial bus interface to control the channel router line cards 418 and 424. The control signals can originate from the test resources of the test platform 204 or through circuitry external to the tester 402.

Interconnects 332, 334, 338 and 340 connect to a second interface plane 432. The fixture 208 is designed to mate to the second interface plane 432 and electrically connect to the interconnects 332, 334, 338 and 340. The probes on in the fixture 208 make a direct connection to nets on the PCB 210. In the adaptor 212 of FIG. 4, the interconnect 332 connects to the probe 320 and the interconnect 334 connects to the probe 318.

FIG. 4 also describes computer readable media 490 containing system software and instructions for execution by the in-circuit test system 402. The adaptor 212 is controlled by the system software that can reside within the computer readable media 490. The computer readable media 490 can be, for example, a ROM, a RAM, a DVD, a hard drive or other computer readable media known in the art.

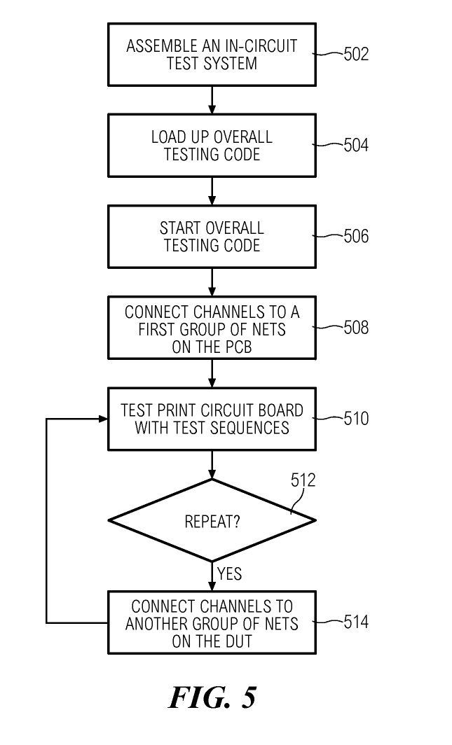

FIG. 5 is a flow chart illustrating the method of operating the adaptor 212.

Block 502 describes assembling the tester 202 with an adaptor 212 in the manner described in FIG. 2. Qualification testing code (block 504) is loaded onto the ICT system 202. The qualification testing code comprises test sequences particular to a PCB line awaiting qualification. The code resides on the computer readable media 490 described above in FIG. 4 and is used by a Central Processing Unit (not shown) within an in-circuit test system to execute the instructions. Alternatively, the code can be executed by a stand-alone computer system that is networked to the tester 202.

Block 506 describes executing the overall testing code on the device under test PCB 210. If the adaptor 212 of FIG. 3 is incorporated into the method described in FIG. 5, the testing code can be segmented into at least two parts to facilitate the qualification of the PCB 210. The overall testing code would entail having the switches connect the channels to a first group of nets on the PCB 210. For example, the switches 322 and 330 would connect the test resource pins 306 and 308 to the probes 318 and 326 respectively, to perform test sequences to qualify a section of the PCB 210 circuitry identified by the first group of nets (block 510).

Qualification is repeated if necessary (block 512) on different sections of circuitry of the PCB 210. The testing code can instruct the switches to connect the test resource pins 306 and 308 to a different group (second and subsequent group) of nets, for example probes 320 and 328, on the PCB 210 (block 514). Test sequences are performed to qualify a different part of the circuitry on the PCB 210. The test sequences are repeated until the PCB 210 has completed the qualification tests (block 512).

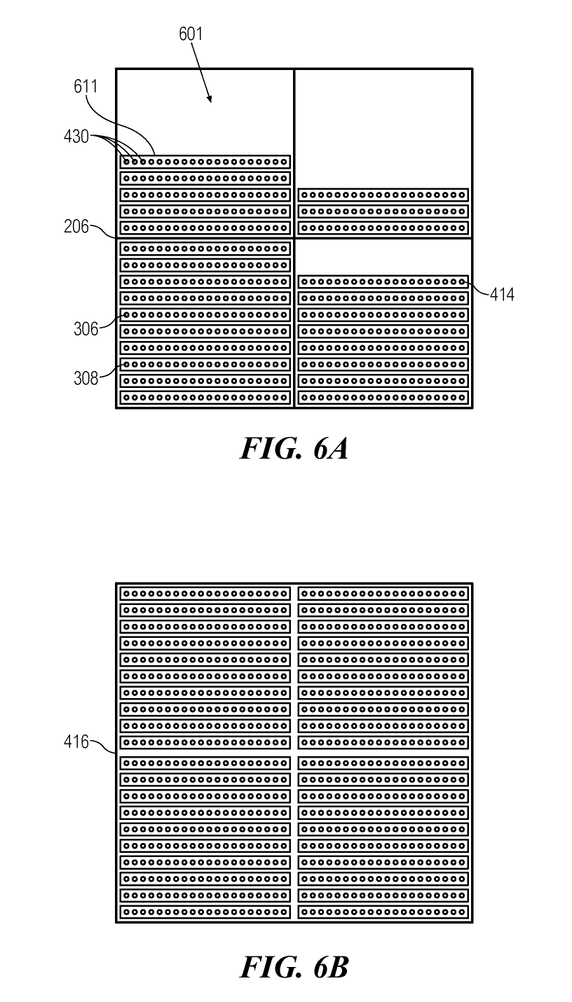

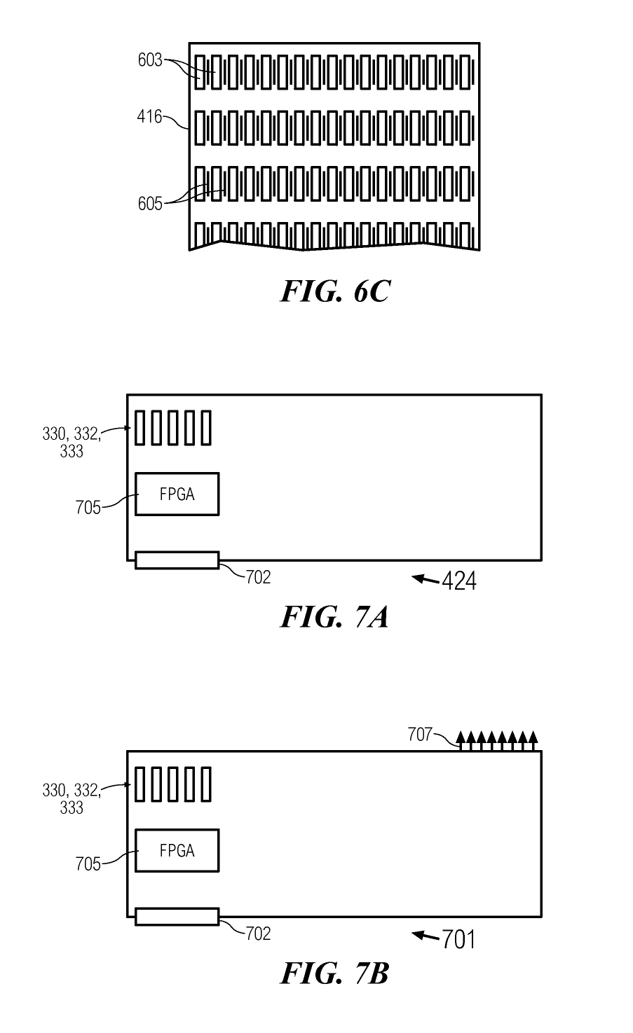

The FIGS. 6A-C are used to describe the modular and scalable aspects of the invention. FIG. 6A illustrates a plan view of the test resource interface 206 and FIG. 6B and FIG. 6C illustrate the bottom view of the adaptor motherboard 416 and top view of adaptor motherboard 416 respectively.

In FIG. 6A, the tester 402 does not have all the test resources 611 within the test platform 204 available for the qualification of the PCB line. A manufacturer may populate test resources 611 into a test platform 204 when deemed necessary. The empty area 601 of the test resource interface 206 identifies unpopulated test resources and presents the scalable nature of the tester 402.

FIG. 6B illustrates the bottom view of the adaptor motherboard 416. The adaptor motherboard 416 is designed to connect to the test resource interface 206 irrespective of the number of test resources populated within the test platform 204.

FIG. 6C illustrates the top view of the adaptor motherboard. Line card mating connectors 603 are used to slot in the channel router line cards 424. Similarly, interconnect mating connectors 605 are used to slot the interconnects 332, 334, 338 and 340 described in FIG. 4. This design illustration allows a manufacturer to use the channel router line cards 424 and the interconnects 332, 334, 338 and 340 as necessary. The design also allows the manufacturer to reuse the channel router line cards 424 and the interconnects 332, 334, 338 and 340 for multiple PCB line qualifications.

FIG. 7A is an illustration of a side view of the channel router line card 418. The channel router line card 418 comprises a mating connector 702, switches 330, 332 and 333, and a field programmable gate array (FPGA) 705. The FPGA allows the manufacturer to reprogram the channel router line card 418 to route test resource pins carrying channel signals between the switches and the mating connector 702. This design example can enable the adaptor invention to be reused for more than one PCB line qualification.

FIG. 7B is a variation of the design of the channel router line card 418 illustrated in FIG. 7A. In FIG. 7B, the interconnects 332 and 334 of FIG. 4 are incorporated into on the channel router line card 701 as connector pins 707. The connector pins 707 will eventually connect to the fixture 208 of FIG. 4. The design of FIG. 7B will require a different layout of the adaptor 212: one that does not require mating connectors 605 for the interconnects 332 and 334 as well as a second interface plane designed to complement the connector pins 707 to connect to the fixture 208.

While the embodiments described above constitute exemplary embodiments of the invention, it should be recognized that the invention can be varied in numerous ways without departing from the scope thereof. It should be understood that the invention is only defined by the following claims.

1. An adaptor to be secured between an in-circuit test system and an in-circuit test fixture, the adaptor comprising switches for electrically connecting single test resource pins to multiple fixture probes.

2. The apparatus of claim 1, wherein control signals instruct the switches to switch the single test resource pins to the multiple fixture probes.

3. The apparatus of claim 1, wherein test sequences pass through the switches to test a printed circuit board, the printed circuit board residing on the in-circuit test fixture.

4. The apparatus of claim 1, wherein a pin from the single test resource pins is routed to a select probe from the multiple fixture probes through one of the switches.

5. The apparatus of claim 1, wherein the in-circuit test system is operated by system software, the system software operable to execute code to control the switches.

6. The apparatus of claim 1, wherein the multiple fixture probes exceed the single test resource pins in quantity.

7. The apparatus of claim 1, further comprising diagnostic test switches to electrically connect the switches together to perform system level diagnostics on the adaptor.

8. The apparatus of claim 7, wherein the switches and the diagnostic test switches reside on channel router line cards, the channel router line cards residing within the adaptor.

9. A computer readable media containing code thereon, the code providing instructions to an in-circuit test system for executing the steps of:
switching single test resource pins to multiple fixture probes through switches, the switches within an adaptor, the adaptor secured between the in-circuit test system and the multiple fixture probes; and
passing test sequences through the single test resource pins, the switches and the multiple fixture probes to a printed circuit board electrically connected to the multiple fixture probes.

10. The computer readable media containing code thereon as recited in claim 9, the code providing instructions to the in-circuit test system for executing the additional step of routing a pin from the single test resource pins through one of the switches to a select probe from the multiple fixture probes.

11. The computer readable media containing code thereon as recited in claim 9, the code providing instructions to the in-circuit test system for executing the additional step of sending a control signal to the switches to route the single test resource pins to the multiple fixture probes.

12. The computer readable media containing code thereon as recited in claim 11, the code providing instructions to the in-circuit test system for executing the additional step of transmitting the control signal and executing test sequences on the printed circuit board.

13. The computer readable media containing code thereon as recited in claim 11, the code providing instructions to the in-circuit test system for executing the additional step of performing system level diagnostics by electrically connecting the switches together through diagnostic test switches, the diagnostic test switches being controlled by the control signal.

14. An in-circuit test system comprising:
a test fixture to interface with a printed circuit board, the test fixture supporting multiple probes;
an adaptor connected to the test fixture and single test resource pins, the adaptor routing the single test resource pins to the multiple probes; and
a test platform containing test resources, the single resource pins providing an electrical interface for the test resources.

15. The apparatus of claim 14, wherein a pin from the single test resource pins is routed to a select probe from the multiple probes.

16. The apparatus of claim 14, wherein the adaptor, the test fixture and the test platform are controlled by system software, the system software residing on computer readable media.

17. The adaptor of claim 14, wherein switches route the single test resource pins to the multiple probes.

18. The adaptor of claim 17, wherein control signals instruct the switches to route the single test resource pins to the multiple probes.

19. The apparatus of claim 18, qualification tests are performed on the printed circuit boards by transmitting the control signals and executing test sequences.

20. The adaptor of claim 18, further comprising diagnostic test switches to electrically connect the switches together, the diagnostic test switches to perform system level diagnostics, and the diagnostic test switches being controlled by the control signals.
